(19) United States
(12) Patent Application Publication
(10) Pub. No.: US 2025/0306571 A1
(43) Pub. Date: Oct. 2, 2025

(54) METHOD IMPLEMENTED BY SOFTWARE INSTRUCTIONS FOR MANUFACTURING A BELT CONVEYOR AND/OR A SERIES OF BELTS CONVEYOR AND RELATED SYSTEM

(71) Applicant: BERGOGNI FOOD MACHINERY S.R.L.S., Felino (PR) (IT)

(72) Inventor: Nicola BERGOGNI, FELINO (IT)

(73) Assignee: BERGOGNI FOOD MACHINERY S.R.L.S., Felino (PR) (IT)

(21) Appl. No.: 19/183,995

(22) Filed: Apr. 21, 2025

Related U.S. Application Data
(63) Continuation of application No. 17/610,480, filed on Nov. 11, 2021, now abandoned.

(30) Foreign Application Priority Data
May 13, 2019 (IT) 102019000006757

(51) Int. Cl. G05B 19/418

(52) U.S. Cl. CPC G05B 19/4182; G05B 19/41805

(57) ABSTRACT

Method for manufacturing a belt conveyor and/or a series of belts conveyor, the method, implemented by software instructions, envisages providing input data associated with technical specifications of the belt conveyor, inputted by a client device, processing said input data associated to the technical specifications, generating corresponding output data that define a technical project related to the one or more belts conveyor.

### CROSS-REFERENCE TO RELATED APPLICATIONS

This application is a continuation of U.S. patent application Ser. No. 17/610,480, filed Nov. 11, 2021, which is a § 371 U.S. National Phase of PCT/IB2020/054511, filed May 13, 2020, which claims priority of Italian Patent Application No. 1020109000006757, filed May 13, 2019, the entire contents of all of which are incorporated by reference herein as if fully set forth.

### FIELD OF THE INVENTION

The present invention is part of the field of belts conveyor for moving products/packages.

### BACKGROUND

For the carrying out of a project and for the subsequent definition of a production bill of materials and corresponding construction and assembly drawings of belts conveyor or lines of belts conveyor, several programs are known in the state of the art, each used to perform a certain work step.

Said programs are generally used within the manufacturing companies and in particular are used by specialized technicians such as for example salespeople for the quoting step, design technicians for the design step and software technicians for the entry into production/carrying out of the belt conveyor.

Said technicians have specialized skills aimed at knowing which data or values are necessary to define the technical specifications of the belt conveyor.

Aforesaid technical specifications can be of various kinds and may depend, for example, on the productive sector in which the belt conveyor has to be inserted, on the products to be moved, on the production rates, on the dimensional specifications of the belt, etc. a. Consequently, the technician is able to make the necessary choices for the carrying out of the project; on the basis of said data, for example the specialized design technician, carries out the correct design of the components and the realisation of corresponding technical bills of material for the production of said belts conveyor, whereby for example the correct size of the belt conveyor, the type of materials with which it must be built, the correct type of chain, the most suitable motorisation, etc. will be defined.

Therefore normally, a user/client who must purchase a belt conveyor must necessarily interface with the specialized technicians of the manufacturing company, who are able to provide first of all a quote and subsequently a project and/or the built belt conveyor.

It follows that the speed of the quoting step and the subsequent steps going from quoting to purchase, entail long times, which are often in contrast with the needs of the users/clients.

Furthermore, the cost of the belt conveyor is also certainly high because it requires the skill of specialized technicians, in aforesaid various operating steps.

As is often the case, the low flexibility of the provision, which is often aimed at carrying out the finished belt conveyor and not, for example, at providing the mechanical components to be assembled, is added to these disadvantages.

### SUMMARY

The technical problem underlying the present invention is in particular that of making available a method for manufacturing a belt conveyor and/or a series of belts conveyor structurally and functionally designed to overcome one or more of the limits set out above with reference to the known prior art.

A main object of the invention is to develop a method for manufacturing a belt conveyor and/or a series of belts conveyor which allows to speed up the design and the manufacturing of the belt conveyor between the client and the manufacturing company.

A further object of the invention is also to make a method available to the art for manufacturing a belt conveyor and/or a series of belts conveyor that can also be used by people without specific technical skills.

These and other objects are reached by the characteristics of the invention as set forth in the independent claims. The dependent claims outline preferred and/or particularly advantageous aspects of the invention.

In particular, an embodiment of the present invention makes available a method for manufacturing a belt conveyor and/or a series of belts conveyor, said method, implemented by software instructions, which provides for
providing input data associated with technical specifications of the belt conveyor, inputted by a client device;
processing said input data associated to the technical specifications;
generate corresponding output data that define a technical design related to said one or more belts conveyor.

Thanks to said method it is possible to speed up the steps of information transfer between client and manufacturing company speeding up the design and manufacturing of the belt conveyor.

According to one aspect of the invention, the method further envisages providing the acceptance of said technical project through the client device.

It still preferably provides for generating the activation of steps related to the carrying out/entry into production of the technical project, following the acceptance by the client.

Thanks to said method, a reduction in the costs for manufacturing the belt conveyor is expected. In fact, said method does not provided for involving specialized technicians during the manufacturing of the project of the belt conveyor, but the software processes said input data associated with the technical specifications and consequently generates corresponding output data that define the technical project.

To speed up aforesaid steps of manufacturing the belt conveyor, the method provides for storing said software instructions implementing the method in a server of the owner.

In particular, it can also provide for connecting said server of the owner and the client device between them by means of a connection network, in particular the internet network.

Said method preferably provides for transferring the input data inputted through the client device to the server of the owner for their processing and generating corresponding output data of the technical project related to said one or more belts conveyor.

Furthermore, one aspect of said method provides for transferring the output data of the technical project processed by the server of the owner to the client device.

Another aspect of the invention is to make available a method wherein the client is able to insert input data in particular to define the technical specifications of the belt conveyor autonomously and directly through the client device, even without having specific technical skills.

In fact, the input data preferably comprise or consist of one or more of the following data: sector data, product data, production data.

Said input data are in fact the strictly necessary data and above all the data that a client, even without specific technical skills, must be aware of for manufacturing the belt conveyor. The method provides for processing, by software instructions, said input data and making the technical choices that define the project by simply inserting aforesaid data without requesting more specific information normally within the responsibility of technicians in the sector. Said input data may also comprise dimensional data, layout data, electrical data, etc., to request all the specifications necessary for the carrying out of the project.

Another aspect of the invention is to make a computer program available for manufacturing a belt conveyor and/or a series of belts conveyor, configured to implement the described method.

Said purposes and advantages are all achieved by the method implemented by software instructions for manufacturing a belt conveyor and/or a series of belts conveyor and related system, object of the present invention, which is characterized by what is provided for in the claims below.

### BRIEF DESCRIPTION OF THE DRAWINGS

This and other features will be more apparent from the following description of some of the embodiments, illustrated purely by way of non-limiting example in the accompanying drawings.

FIG. 1: illustrates the system for manufacturing a belt conveyor and/or a series of belts conveyor, configured to implement the method of the invention.

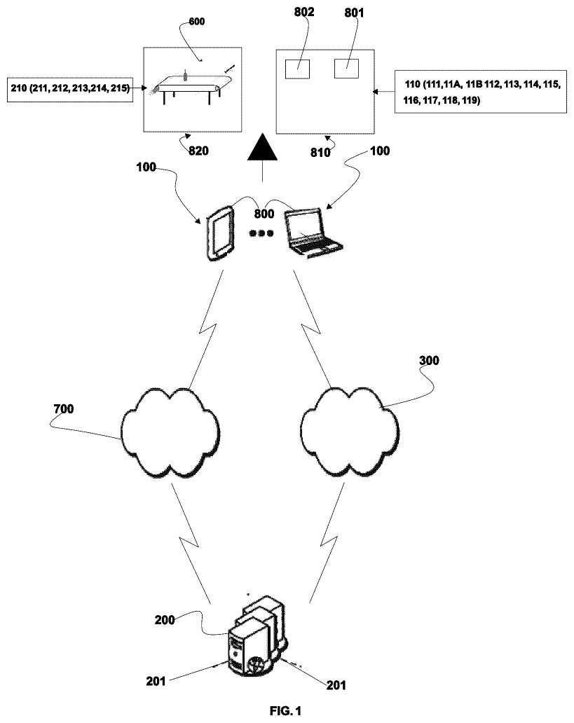

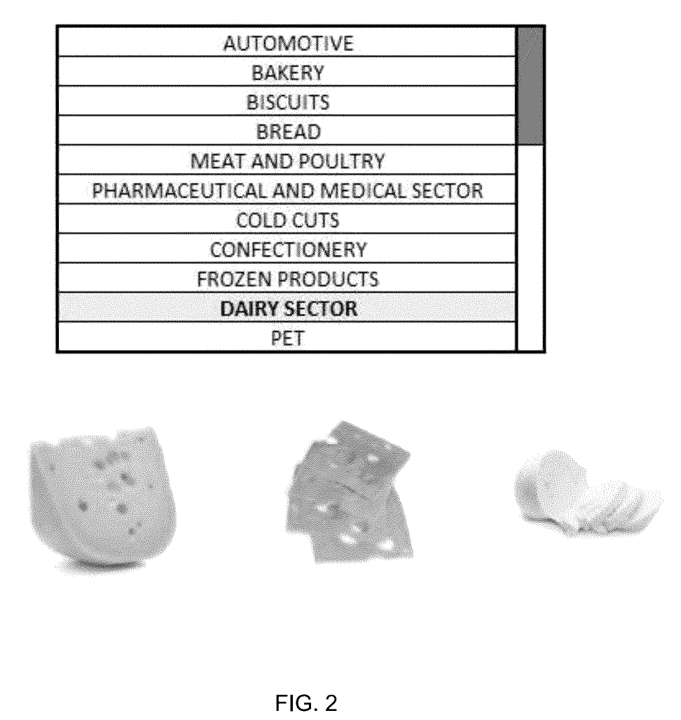

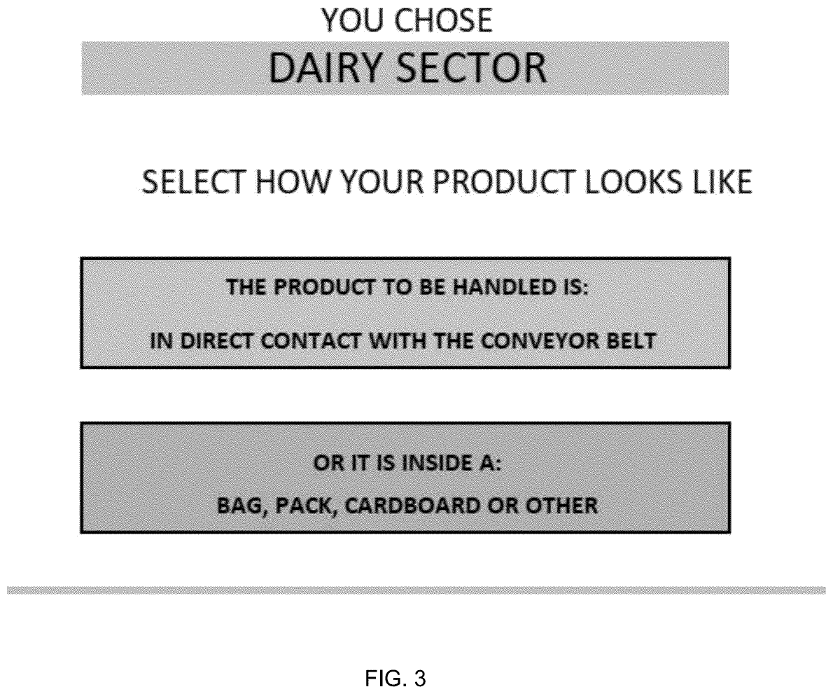

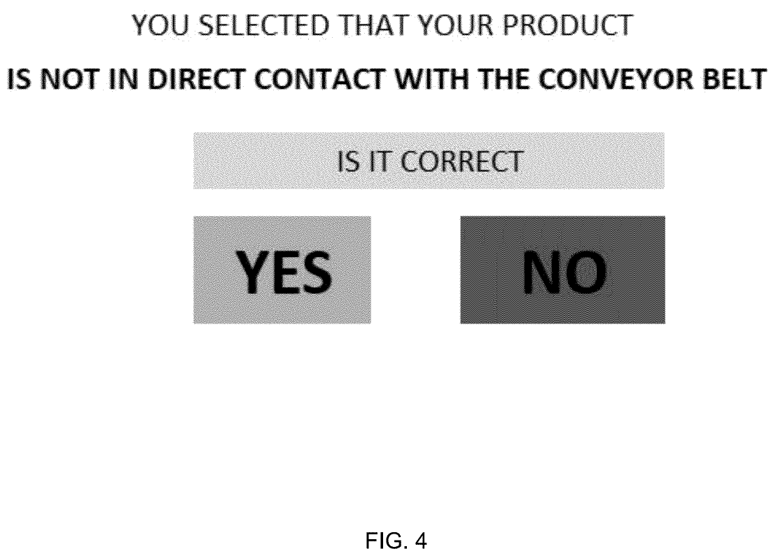

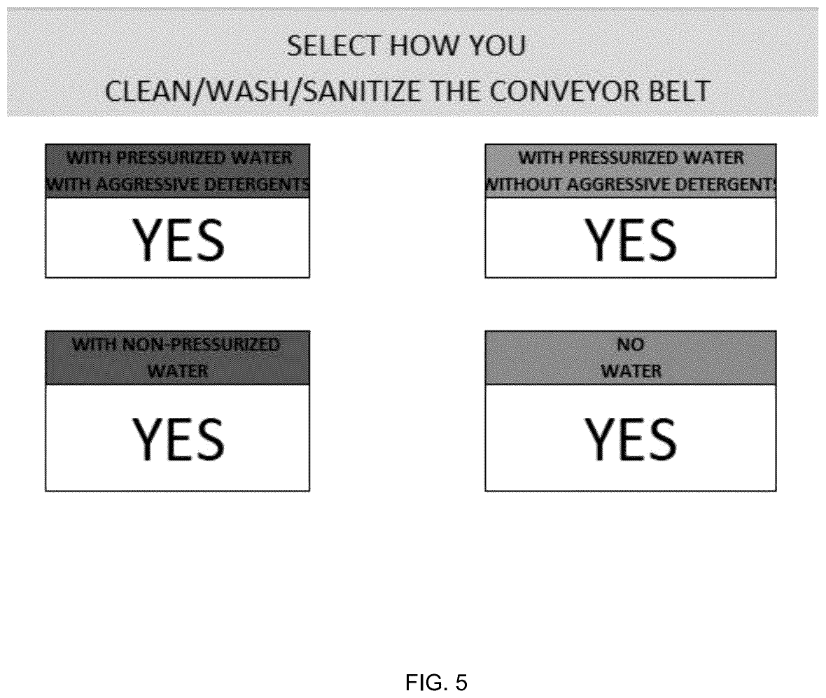

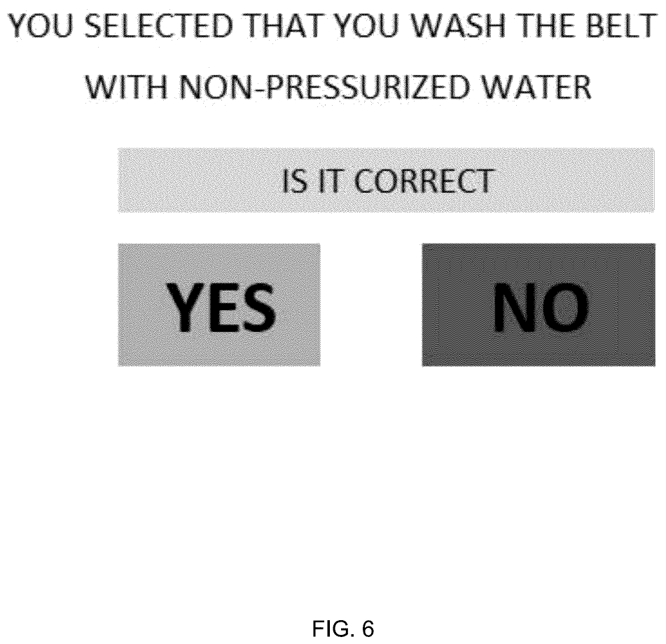

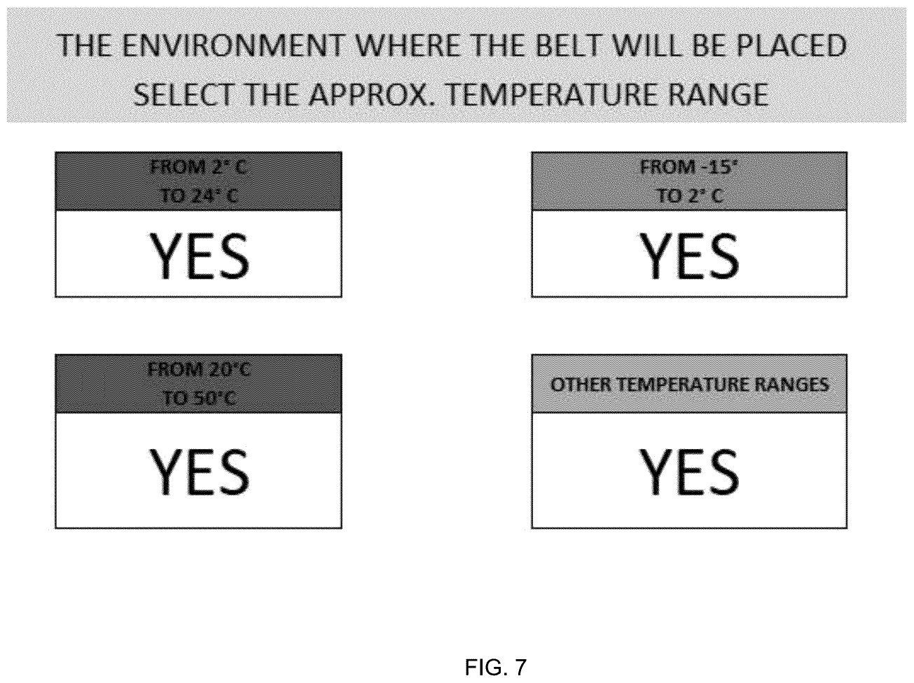

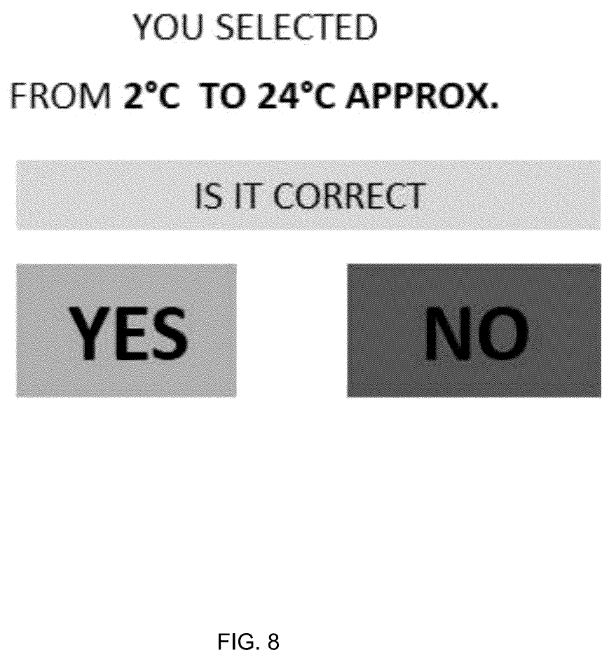

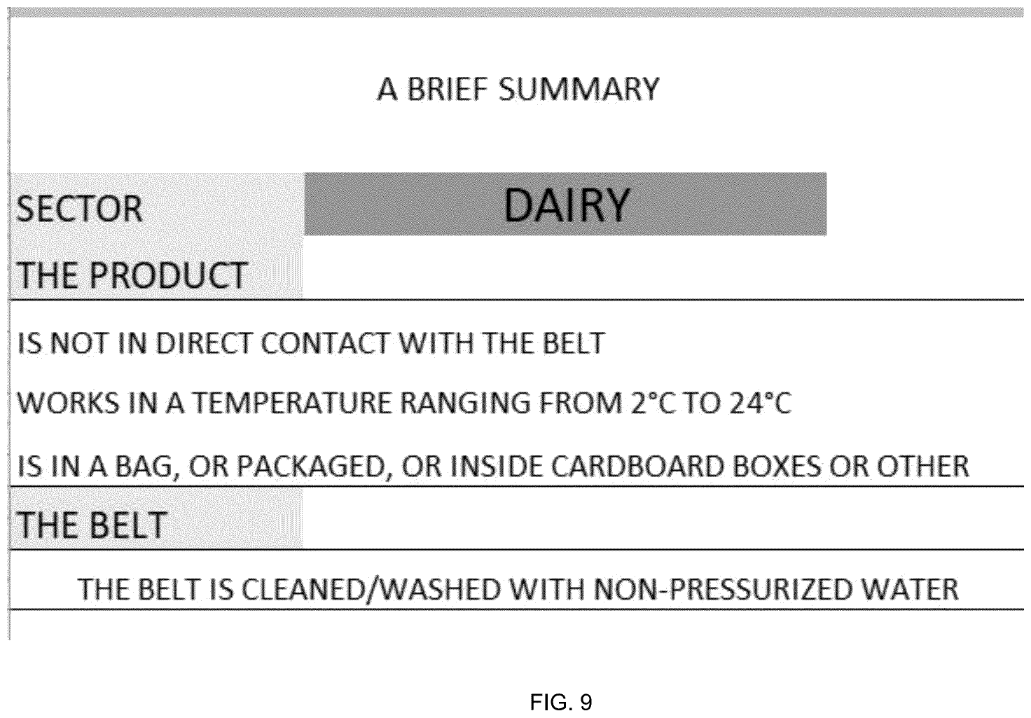

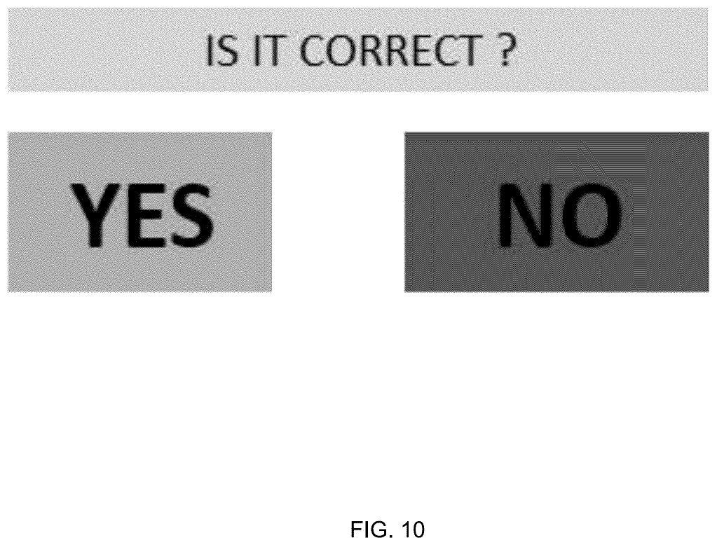

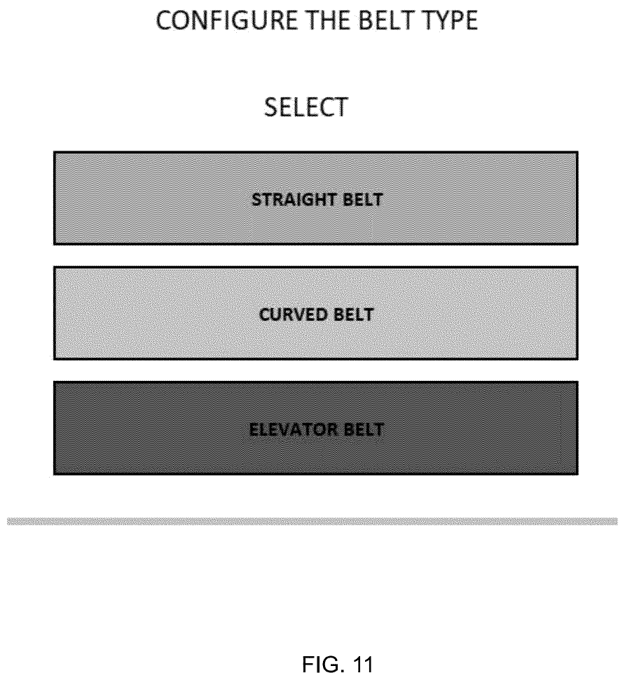

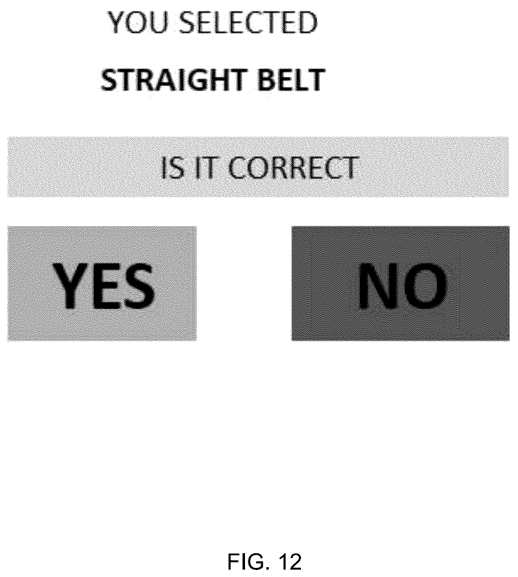

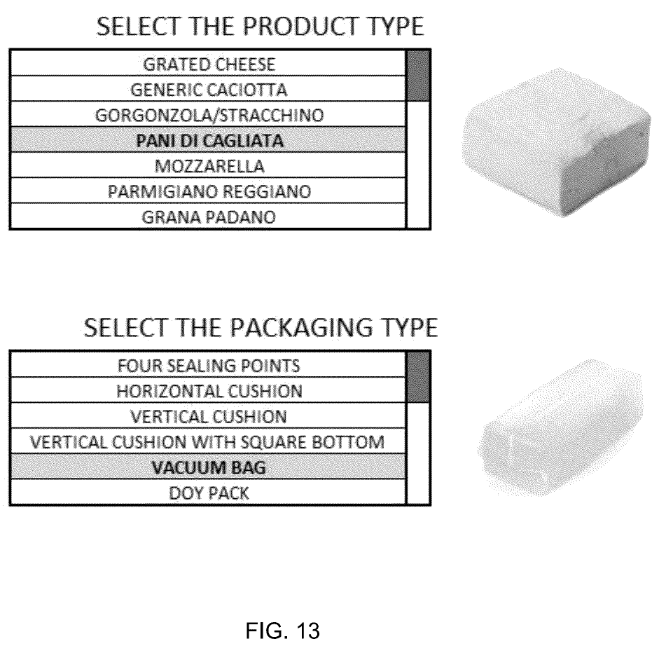

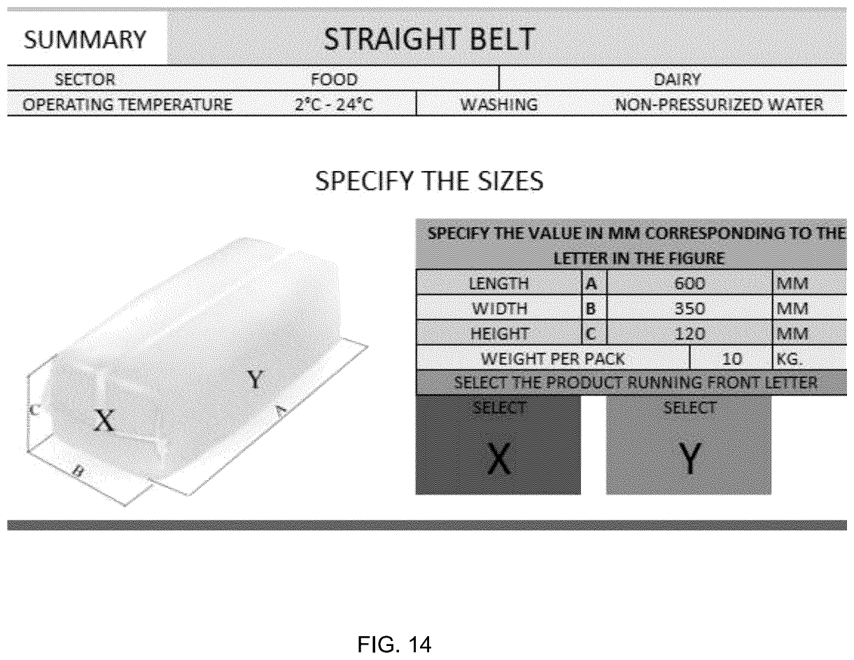

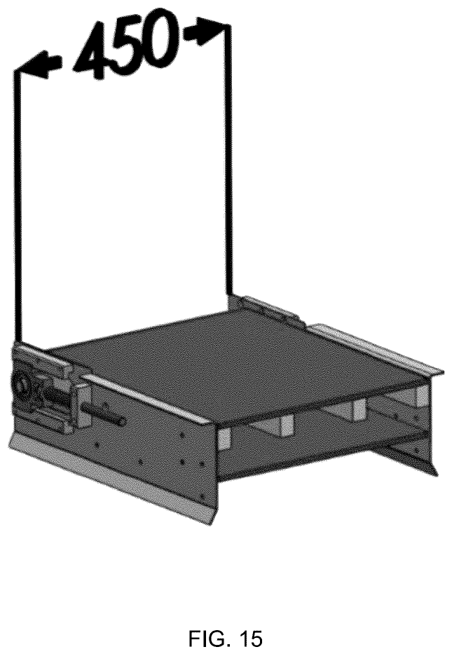

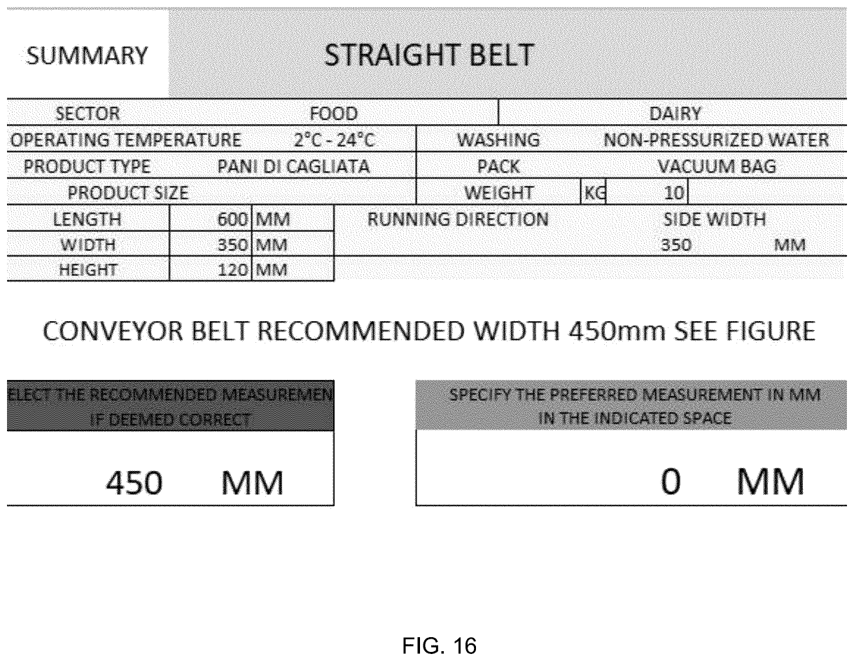

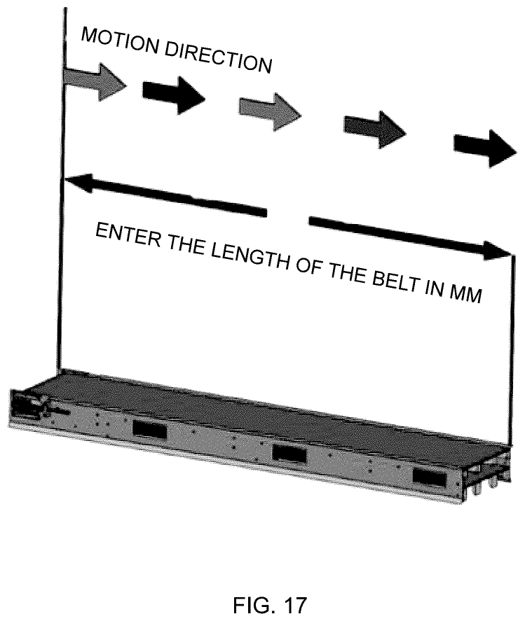

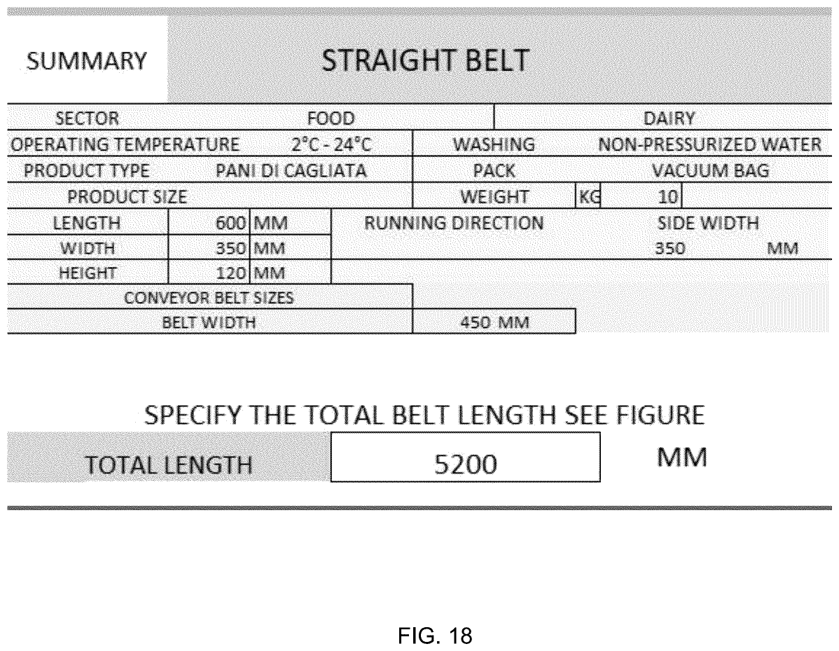

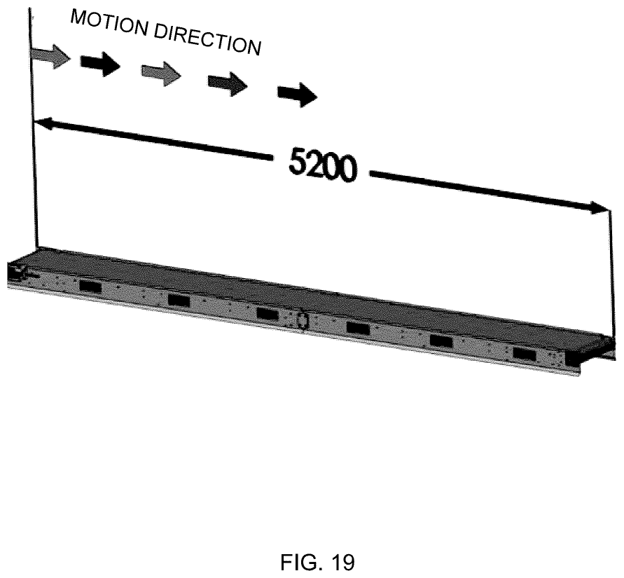

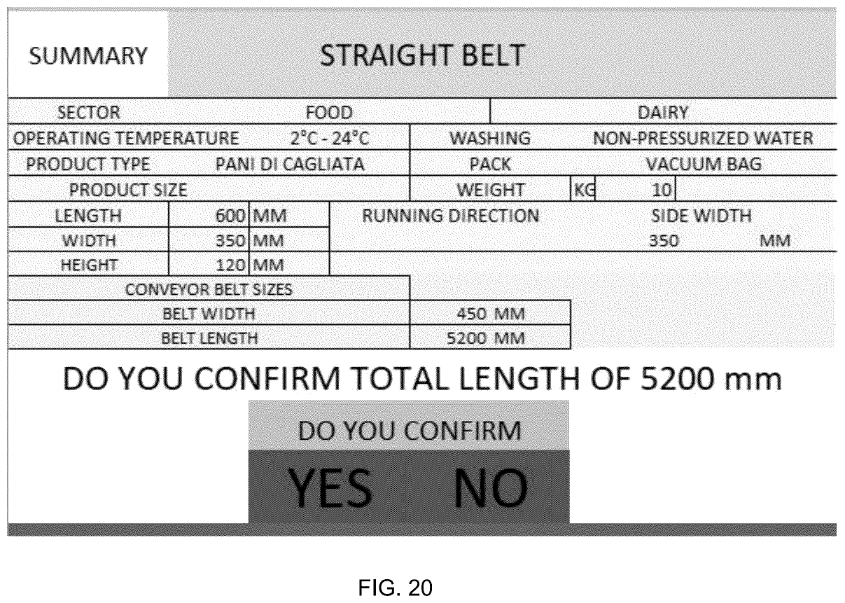

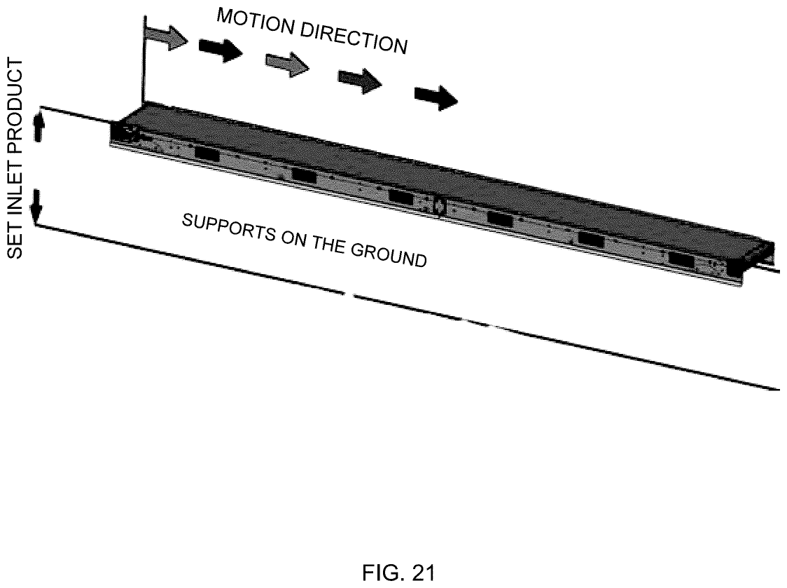

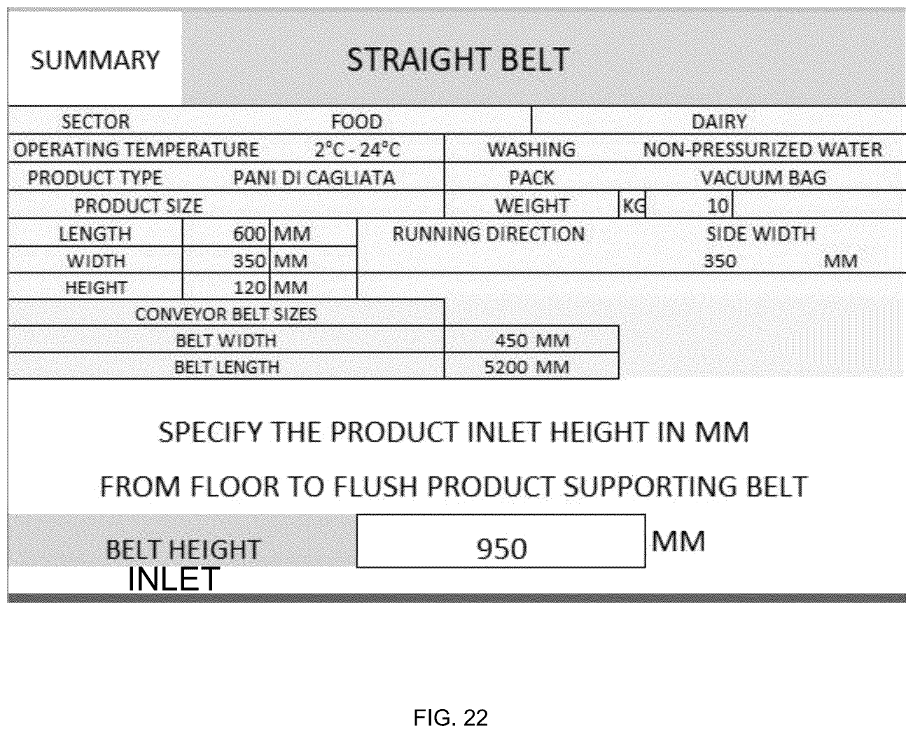

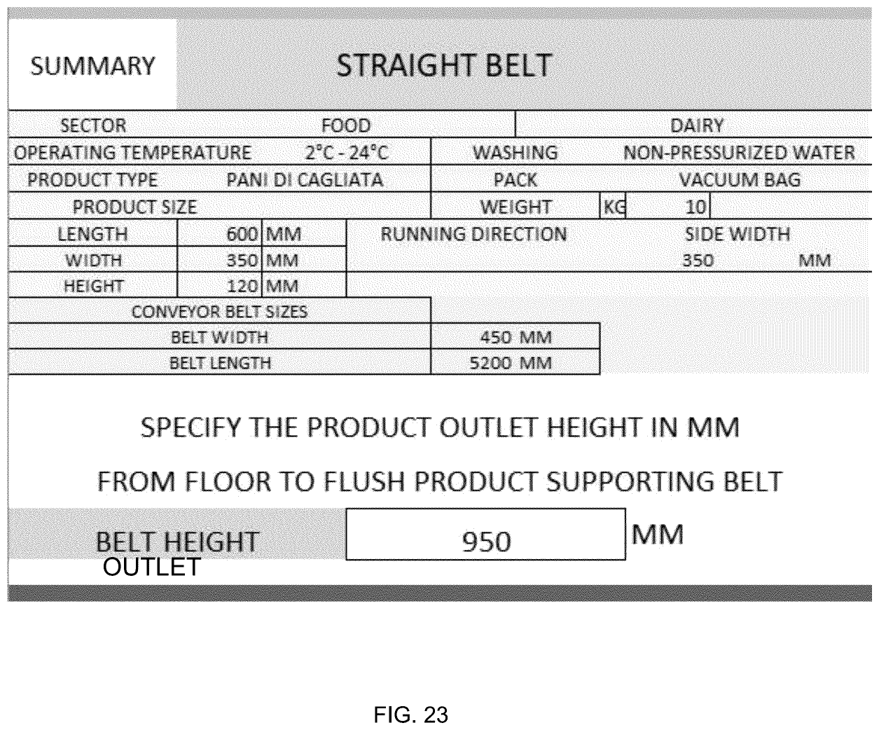

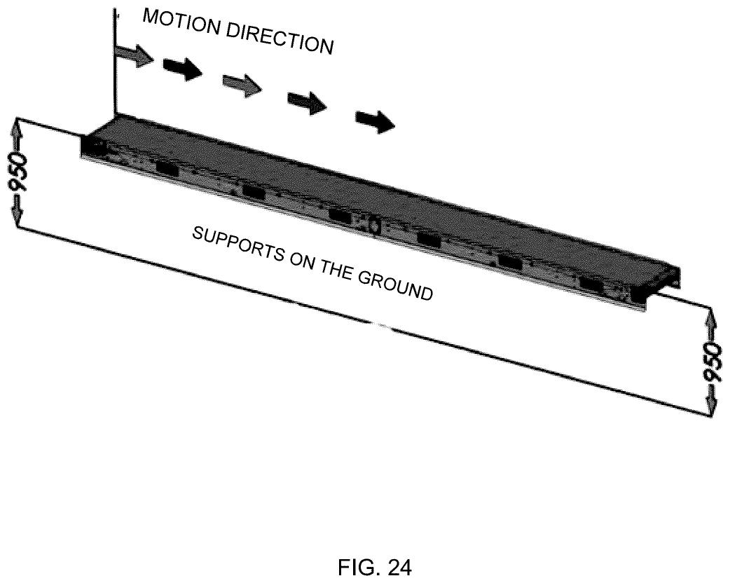

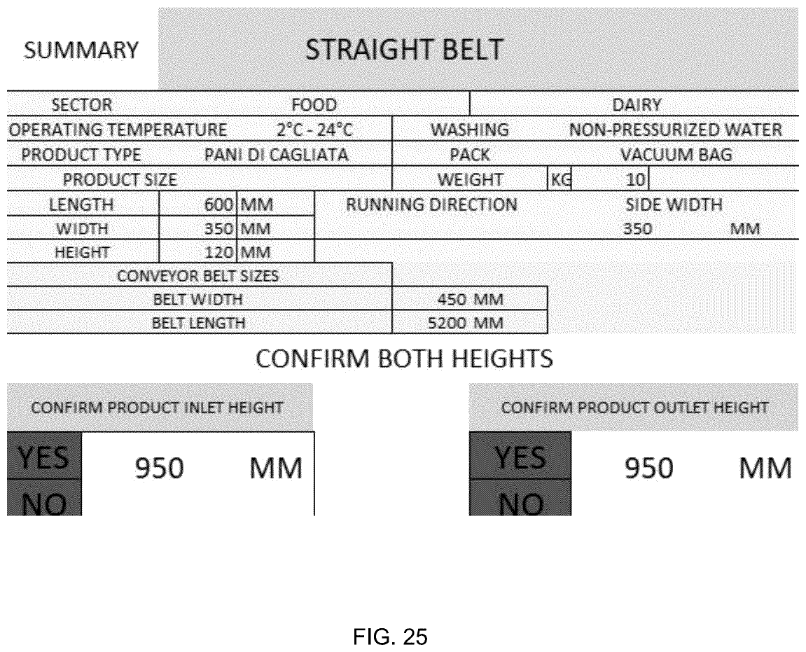

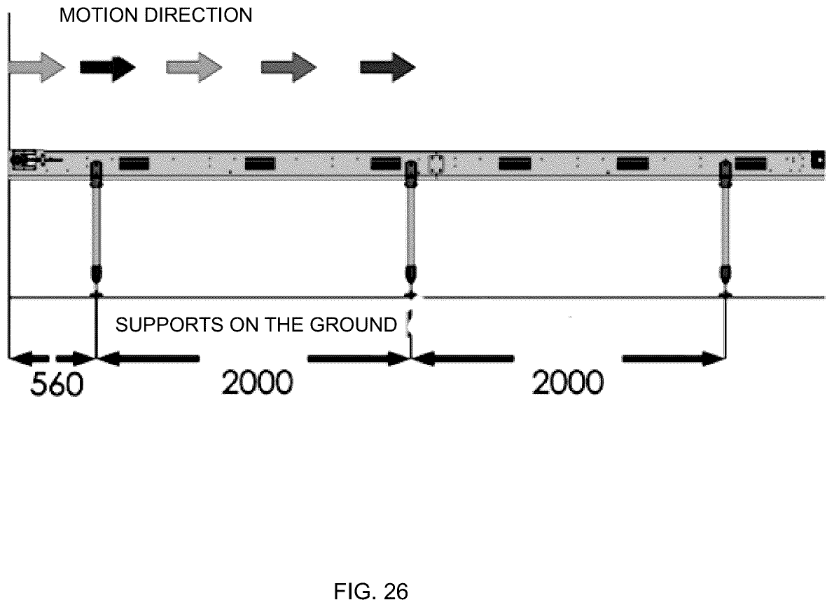

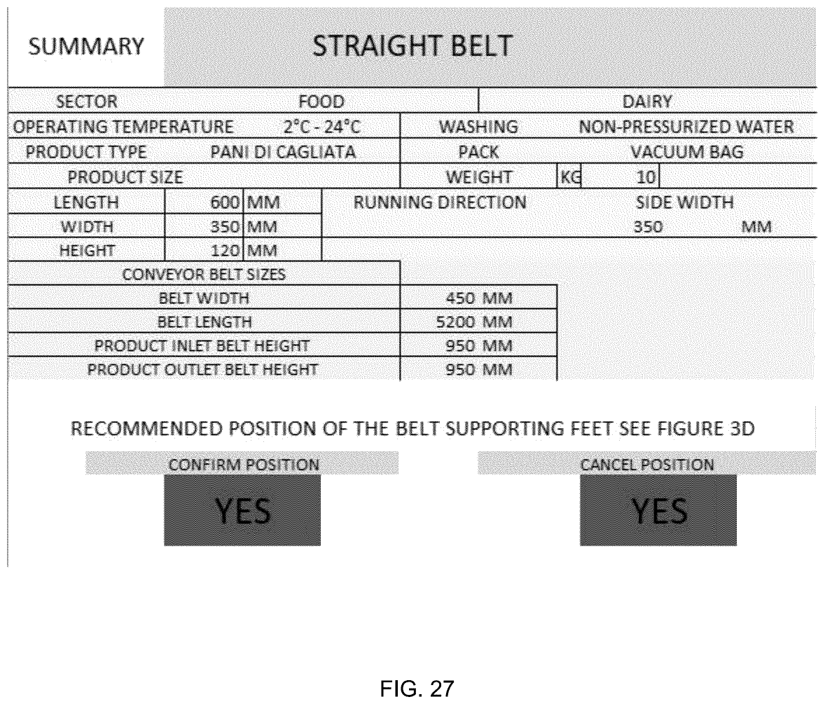

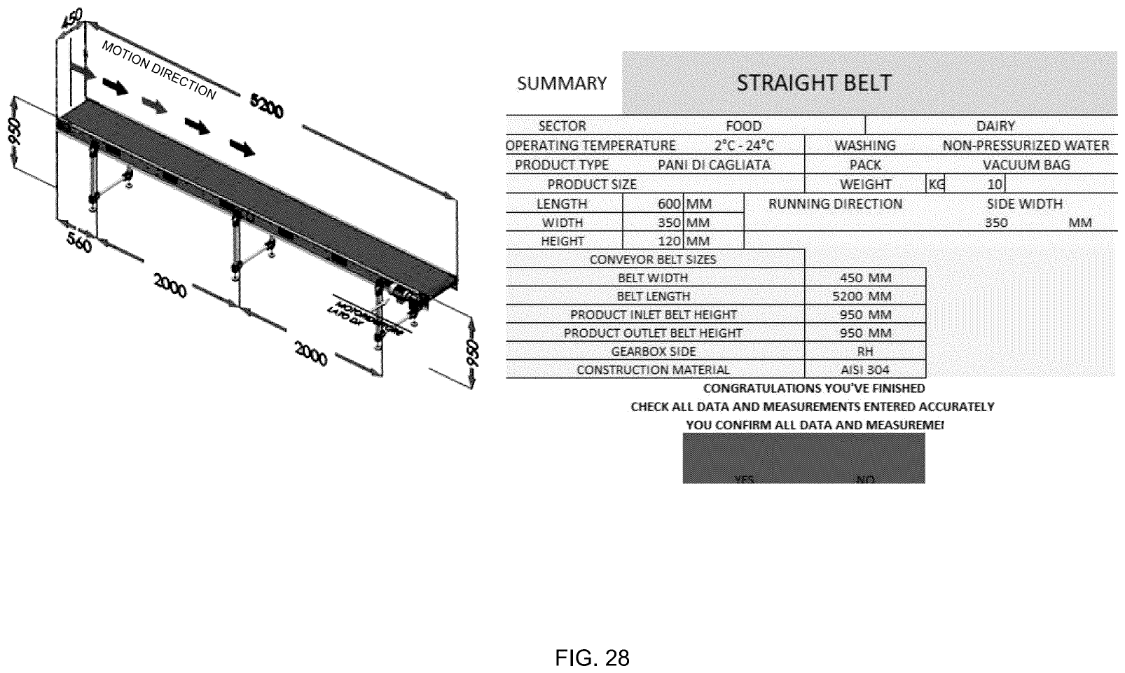

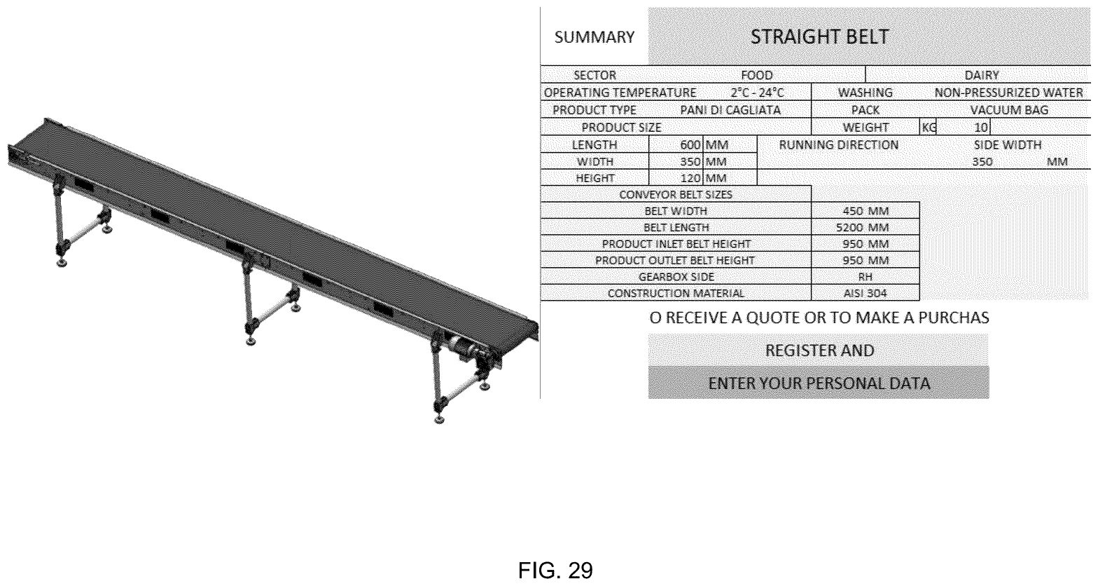

FIGS. from 2 to 29: illustrate an example of an input interface with the input data requested from the user.

### DETAILED DESCRIPTION OF THE PREFERRED EMBODIMENTS

Belts conveyor for moving products/packages are generally part of lines for the production of said products/packages.

Said belts conveyor connect, for example, the various production stations.

The conformation of said belts conveyor is extremely customised, that is to say, it has technical characteristics which vary from project to project and are dedicated to the client's specific production needs.

In fact, said belts conveyor must respond to different technical requirements linked to several aspects, such as for example the characteristics of the products/packages to be moved, the layout of the production line in which said belts conveyor are to be inserted, etc.

These and other important features for the customised design will be described in more detail below.

Precisely because the belts conveyor require a very customised design, in order to ensure the productive needs of the lines in which they are inserted, it is essential that the client interfaces with the manufacturing company of said belts conveyor and in particular with the specialized technicians such as for example:
salespeople for the quoting step,
design technicians for the design step
software technicians for the entry into production/carrying out of the belt conveyor.

Said specialized technicians generally carry out the design and/or quoting and/or production activities of the belt conveyor, by means of software programs, each dedicated to said specific activities.

The client, even if he is competent the field of design of belts conveyor and in particular if not competent, is not autonomous in the definition of the project and must therefore interface with various people of the manufacturing company.

It follows that the speed in the execution of the various steps, from quoting/design, up to the purchase and manufacturing of the belt conveyor, entails long times, which are often in contrast with the needs of users/clients.

As a direct consequence there are also high costs of the belt conveyor precisely due to the low automation of the process, which requires an important involvement of highly specialized people for each step of analysis and carrying out of the project of the belt conveyor.

A method implemented by software instructions and related system, operating by software instructions, having the purpose of allowing a generic client to define a project related to a belt conveyor and/or a series of belts conveyor in a simple and fast way is the object of the invention.

Said method provides for:
providing input data 110 in particular adapted to define technical specifications of the belt conveyor, inputted by a client device 100;
processing said input data 110 in particular adapted to define the technical specifications;
generating corresponding output data 210 that define a technical design 600 related to said one or more belts conveyor.

Therefore, the client, by means of his client device 100, for example a computer, a mobile phone, or any other instrument similar to them, enters input data 110 in particular adapted to define technical specifications of the belt conveyor, necessary for the definition of the related technical project 600.

According to an aspect of the invention, said method preferably provides for using a user graphic interface 800 comprising an input interface 810 of the client device 100 to provide the input data 110.

In this way, as will be explained in detail below, the client is able to insert the input data 110 to define the technical specifications of the belt conveyor autonomously and directly using the client device 100. Therefore, directly through the input interface 810 it is possible to insert all the input data 110 without having to communicate through different systems and/or interface with the manufacturing company.

This facilitates the insertion step of input data 110 also thanks to the fact that, as will be described in more detail below, the input interface 810 is configured to help and guide the client to insert all data input 110 necessary for the definition of the technical project 600.

Preferably, said method also provides for using the user graphic interface 800 comprising an output interface 820 of the client device 100 to display output data 210 that define the technical project 600.

Thanks to this solution, the client receives all the information related to the technical project 600 through the output interface 820 without having to use different systems and/or communication interfaces with the manufacturing company.

For carrying out said method, a preferred embodiment provides for connecting said client device 100 by means of a connection network 300 with a server of the owner 200, i.e. for example a server of the company manufacturing the belts conveyor.

In particular said connection network 300 can be, for example, an internet network.

According to an aspect of the invention, said method provides for storing the software instructions implementing the method on said server of the owner 200.

Therefore, the input data 110, inputted by the client device 100, are preferably transferred to the server of the owner 200 for their processing by the software instructions and consequently for generating corresponding output data 210 of the technical project 600 related to said one or more belts conveyor.

Consequently, said method may provide for transferring the output data 210 of the technical project 600 processed by the server of the owner 200 to the client device 100.

Thanks to this solution, the client receives directly on his client device 100 the technical project 600 processed by the server of the owner 200 by the software instructions.

Therefore, also the step of receiving the technical project 600 takes place automatically and directly from the server of the owner 200 to the client device 100, preferably through the output interface 820.

Said method may further provide for processing said technical project 600 for the definition of a corresponding financial project 700.

The method preferably envisages providing the acceptance of said technical project 600 and/or financial project 700 through the client device 100.

Following the acceptance of the technical project 600 by the client, it is possible to generate the activation of steps related to the carrying out/entry into production of said technical project 600.

The client therefore does not need to interface with specialized technicians or people from the company for the reception and transfer of the information related to the input data 110 or technical project 600.

The speeding up of the process of data acquisition and project processing is therefore evident. For example, in fact, the quoting and definition step of the finished technical project can take a few minutes (less than 10 minutes), compared to a process according to the prior art which generally provides for 15/20 days only for the provision of financial data and general technical data, without achieving the finished technical project.

Another aspect of the invention is to make available a method in which the client is able to insert the technical specifications of the belt conveyor autonomously and directly by means of the client device, even without having specific technical skills.

Preferably, said method in fact provides for:
displaying through a client device 100 a list of input data 110, in particular that do not require design knowledge, for the definition of the technical specifications of the belt conveyor,
requesting to the user the selection of the displayed input data 110 through the client device 100,
preferably processing said selected input data 110, so as to propose/request further input data 110 which the user must select and which are dependent on the previously selected input data 110,
preferably processing said selected input data 110, so as to generate output data 210 for the definition of a technical project 600 related to said one or more belts conveyor.
In this way, thanks to the display through a client device 100 of a list of input data 110, the user is guided in the insertion, as he has to easily select what is proposed; also, the fact of processing said selected input data 110, to generate a further input data 110 that the user must select, simplifies the choice of the user who does not need to make excessive considerations or deductions. The processing, which will be better explained below, of said selected input data 110, to generate output data 210 which define a technical project 600 related to said one or more belts conveyor, makes the system usable even by those without technical skills and speeds up the carrying out of the technical project.

The input data 110 preferably are only the strictly necessary data and above all the data of which a client, even without specific technical skills, must be aware of for manufacturing the belt conveyor. Therefore, no more specific information is required which is normally the responsibility of technicians in the sector.

In particular, precisely to facilitate, on the client's side, the insertion of said input data 110, the method provides for requesting the input data 110 which are used to determine the type of belt, that is, for example, to determine the type of material of the structure, type of chain, type of guides, type of bearings, etc.

The method in fact preferably provides for requesting input data 110 which comprise and/or consist of one or more of the following:
sector data 111 to request and receive technical specifications related to the productive/industrial sector which the belt conveyor and/or the series of belts conveyor has to operate in; in fact, the productive/industrial sector influences the definition of the belt conveyor. A food sector, or an automotive or pharmaceutical sector, needs belts conveyor with very different technical characteristics. The choice of the productive/industrial sector directs the project 600 by limiting the possible variants of the belt conveyor in order to delete those unsuitable for that specific sector.
usage and maintenance data 111A to request and receive technical specifications related to the type of maintenance that is envisaged for the belt conveyor such as cleaning, washing or sanitizing; the usage and maintenance data 111A normally depend on the previous sector data 111.
environmental data 111B to request and receive technical specifications related to the characteristics of the environment in which the installation of the belt conveyor and/or the series of belts conveyor is provided for, of humidity, temperature, etc.; the environmental data 111B normally depend on the previous sector data 111.
product data 112 to request and receive technical specifications related to the product and/or products to be moved by the belt conveyor and/or the series of belts conveyor; for example the type of packaging, the dimensions, the weight of the product, etc. are included in the product data;
production data 113 to request and receive technical specifications related to the production rate that the belt conveyor and/or the series of belts conveyor have to ensure; for example, the number of products per minute or per hour that the belt must move will be requested.
   b. Furthermore, the method can also provide for the insertion of:
dimensional data 114 to request and receive technical specifications related to the dimensional characteristics of the belt conveyor and/or the series of belts conveyor; for example, the width, length, height of the belt conveyor.
layout data 115 to request and receive technical specifications related to the positioning related to the entire operative area of the belts conveyor;
electrical data 116 to request and receive technical specifications related to the electrical specifications;
provision data 117 to request and receive technical specifications related to the provision, required by the client/user. For example, how it should be sent, to which address, at what time, etc.

A feature of said method also provides that the input data 110 also comprise one or more of the following:
purchasing data 118 for the confirmation of the technical project and corresponding financial project for the continuation of the purchase;
registration data 119 to request and receive information related to the data of the client/user who has made the request.

Thanks to said further input data 110, the acceptance of the project 600 and its subsequent provision to the client is finalized.

In this way, as will be described in detail below, as a function of the purchasing data 118, the client can choose the type of provision necessary to him in particular by acceptance, of the steps for the carrying out/entry into production of the technical project 600.

In this way, even a client/user/user who does not have specific technical skills regarding belts conveyor, is able to provide all the input data 110 necessary for the definition of the project.

Furthermore, as will be further explained below, the user is guided in inserting said input data 110 and therefore does not risk forgetting necessary information.

Furthermore, the client does not even have to provide complex input data 110 which are the responsibility of the technician in the sector.

In fact, no technical information is requested related to the belt conveyor, such as for example the type of chain, the type of construction material of the belt conveyor, the type of guides, etc.

For example, the client must provide product data 112 and/or sector data 111 without worrying about defining the type of chain suitable for transporting that particular product.

As explained below, the software instructions, which process the input data 110 associated with the technical specifications, will provide the corresponding output data 210 related to the most suitable type of chain or even the possibility of choosing between several suitable types will be granted.

Again, with the aim of facilitating the client, in the step of insertion of the input data 110, a preferred embodiment of said method provides that on the basis of the provided input data 110, further input data 110 depending on the preceding ones are required.

To do this, the method can provide that the input interface 810 comprises one or more of request fields 801 of the input data 110 to define the technical specifications of the belt conveyor and corresponding one or more of insertion fields 802 to receive the input data 110 which define the corresponding technical specifications of the belt conveyor.

Preferably said insertion field 802 is configured to receive a value/string or is configured to provide one or more selectable options.

Here are some examples of the input data 110 provided and of those further requested and dependent on those previously provided.

The sector data 111 can be for example:
food sector,
beverage sector,
automotive sector, etc.

Furthermore, on the basis of the insertion of the sector data 111, for example the food sector, it may be required to specify:
Breadmaking,
Dairy,
meats and cured meats, etc.

Furthermore, for example, on the basis of the insertion of the dairy data, it may be required to specify product data 112 to define whether the food is in direct contact with the belt conveyor or not and the corresponding insertion field 802 could therefore be configured to provide one or more selectable options for example: yes or alternatively no.

Another example may relate to a further product data 112 to provide the number of the different types of products with which the belt is to be used. In this case the relative insertion field 802 is configured to receive a value for example: from 1 to 100.

Consequently, it may be required to insert the product data 112, necessary to define the type of packaging of a first product. The corresponding insertion field 802 could therefore be configured to provide one or more selectable options related to the packaging, for example:
smooth plastic
film
tray etc.

By selecting the option, smooth plastic, furthermore the insertion of product data 112 related to the dimensions of the first product 1 may be requested:
width in mm
height in mm
length in mm

As regards the production data 113, the production speed of the first product can be requested, for example in pieces per minute.

The same information will be requested in sequence for all the different products inserted.

Other requested data may be for example dimensional data 114 of the belt conveyor:
useful length of the space in which to insert the belt conveyor
shape of the belt conveyor

In the latter case, the corresponding insertion field 802 could therefore be configured to provide one or more selectable options, for example:
straight belt,
curvilinear tape,
etc.

By selecting the curvilinear option, further dimensional data 114 will be requested, for example:
first straight part, in which to insert the measure, for example in mm,
first curve, in which to insert the measure in degrees of the curve,
first curve, in which to insert the measure, for example in mm of the minimum internal radius of the curve
second straight part in which to insert the measure in mm,
height from the ground of the product inlet area in which to insert the measure, for example in mm,
height from the ground, in which to insert the measure for example in mm.

It is understood however that what is described above has a value of non-limiting example, therefore, possible variants of detail that may be necessary for technical and/or functional reasons, are considered from now falling within the same protective scope defined by the claims indicated below.

As regards instead the output data 210, they are preferably defined as portions of codes or complete identification codes of respective components or parts of the belt conveyor.

For example, the term “codes” refers to an alphanumeric list that uniquely defines a component of the belt conveyor; said code can be associated, that is can identify a mechanical/electrical component of the belt, as well as a drawing of a constructive detail 213 and/or an assembly drawing 214, or in general with a document 215 correlated to the conveyor.

Said codes in particular are adapted to identify and/or compose a technical basic bill of materials 212 and/or a drawing of a technical project 600 related to said one or more belts conveyor.

The term bill of materials 212 refers to an identification code of a belt conveyor or a part thereof, which in turn comprises a list of codes that identify all the components that together make up a belt conveyor or a part thereof.

Therefore, the output data 210, preferably in the form of codes, may comprise one or more of the following data:
a partial and/or total graphic image 211 adapted to display a partial and/or total configuration of the belt conveyor and/or the series of belts conveyor;
a technical bill of materials 212 of the belt conveyor or part thereof,
corresponding drawings of the construction details 213,
assembly drawings 214,
technical manuals 215 for the assembling and operation of said one or more belts conveyor.

Thanks to the output interface 820 of the client device 100 it is possible to display output data 210 which gradually define the technical project 600.

For this purpose, an aspect of said method provides for being able to interact with the output interface 820 to modify the technical project 600 directly from the client device 100. In particular, it is possible to operate directly on a graphic image 211 displaying the project 600.

Therefore, some input data 110 previously described, for example some dimensional data 114, can be inserted or modified directly by the output interface 820. The client therefore just has to insert data in a more intuitive way, being them inserted directly on the graphic image 211 which displays the project 600.

The method provides, on the basis of the input data 110 provided, that further input data 110 are required.

Said request for further input data 110 is preferably dependent on said input data 110 previously provided.

Furthermore, the method provides that the processing of the input data 110 takes place through a plurality of stages or steps in cascade with the entry of input data 110 by the user, in particular in the form of predefined input data 110.

In particular, each subsequent entry step is preferably chosen as a function of the previous entry step.

Preferably each step provides for a series of questions configured for the selection of corresponding input data 110 in which each choice of a given input data 110 defines a subsequent step which provides for further questions and a corresponding subsequent selection of input data 110 to be selected until an output data 210 is generated which uniquely defines a component or part of a belt conveyor. Said output data 210 at the end of a step is at least a portion of code which is completed with the subsequent steps until a complete code is generated adapted to define a technical bill of materials 212 and/or a drawing of a technical project 600 related to said one or more belts conveyor.

The processing step for generating an output data 210 can also comprise the execution of calculations by means of spreadsheets or the use of tables which, as a function of the values inserted in the input data 110, will size and/or select components of the belt conveyor, such as mechanical carpentry parts or motorisations, or pinions, or chains, etc.

An example can be given by the dimensional data of the product and productive rate data, which are functional in defining the speed and power of the belt motorisations as well as the type of chains and pinions etc.

Said spreadsheets or tables are prepared by expert designers in the sector and are inserted in the software carrying out this method.

A possible embodiment provides that at the end of each step an output data 210 is defined which is at least a portion of the code. Said code, for example alphanumeric, will be completed with the subsequent steps until a complete identification code for a respective component or part of the belt conveyor or of the complete conveyor is generated.

Preferably, said method also provides for defining an input database for the input data 110.

Said database can comprise a plurality of input databases each comprising input data 110, in particular in the form of predefined input data 110, preferably divided by type of input data 111, 111A, 111B 112, 113, 114, 115, 116, 117,118, 119.

Preferably each input database is correlated in cascade with further databases dependent on the input data 110 of the previous database.

For example, the input database related to the sector data 111 comprises the following sector data 111: food, pharmaceutical, automotive sector, etc.

By selecting the food sector data, this gives access to a database correlated thereto and in cascade, which proposes a series of options that are specific to the food sector, for example a database that contains input data 110, which the user must select, related to the different types of food sector: dairy, breadmaking, beverage, etc. And so, on until all the input data 110 of each database in cascade has been selected by the user.

A further possible embodiment of the method may provide for an input database comprising input data 110 in which the selection of said input data 110 restricts said database to an increasingly reduced set of options, that is, of input data 110 to be selected which has the properties of the input data 110 already inserted.

In this case a single database is meant, containing all the possible selectable options of input data 110, in which the chosen input data 110 gradually reduce the number of remaining options. And so on until the database no longer contains selectable options.

For example, by selecting as input data 111 that the work sector in which the belt conveyor is placed is of the food type, the database reduces the set of selectable data; for example, all the flanks made of materials other than stainless steel or aluminium are deleted from the input database; by subsequently inserting as product data 112 that the product is not packaged, but in bulk, the database further reduces the set of data that can be selected by the user; for example, all the flanks in materials other than stainless steel are deleted from the input database. And so on.

According to an aspect of the invention, the method also provides for defining an output database comprising the output data 210.

In said database, all the possible output data 210 are collected which can be used for manufacturing the belt conveyor and in particular all the possible codes that are used to compile a technical bill of materials 212 or a technical project 600.

Preferably each stage or step in cascade of entry of input data 110 generates an output data 210 which is a code or portion of code contained in the output database.

All the cases of well-defined codes that correspond to each single component/element/part of all the types and cases of belt conveyor that the user can create are inserted into the database. a. All these codes that will make up the output database are created beforehand, after an accurate and crossed study, developed with a mechanical design performed, with the normal 3D and 2D CAD programs existing on the market, by technicians specialized in the sector of belts conveyor.

As said codes are associated both with physical components of the belt and with drawings of construction details 213 and/or assembly drawings 214 of the conveyor, or documents 215, the output database also comprises all the drawings of the assembled belt 214 and/or the drawings of the construction details 213 and/or documents 215 of all the types of possible belts conveyor, for the transport of all kinds of products, for each single belonging sector.

All said construction 213, and assembly drawings 214, technical bills of materials 212, maintenance user manuals 215 etc., which will make up the output database are created beforehand, after an accurate and crossed study, developed with a mechanical design performed with the normal 3D and 2D CAD programs existing on the market, by technicians specialized in the sector of belts conveyor.

All said drawings 213, 214, bills of material 212, manuals 215 etc., are coded with identification and belonging codes for each single drawing, part or document, and inserted as an alphanumeric code into the database.

As a function of the input data 100 inserted by the user, said method can provide for identifying the output data 210 by searching the output database for the respective component codes, drawings 213, 214, bills of materials 212, manuals 215, etc.

Said output data 210 contained in the respective output database can be grouped depending on the functional groupings that the technicians of the sector normally apply for manufacturing the belts conveyor.

In fact, a belt conveyor generally consists, for example, of flanks, guides, support elements, motors, etc., which are mounted together to make groups of components of said belt or said complete belt conveyor.

To simplify the steps of processing and choice of the output data 210 in particular an identification code of a component, specific output databases for the respective components may be present, for example database for the flanks, the guides, the support elements, the motors, etc.

For example, the output database of the flanks can contain all the different types of flanks, for example by shape, length, height or by material, etc.

Each input data 110 inserted will restrict the choice within said output database of the flanks for the definition of the final flank code.

Preferably, all the codes that make up the output database are a portion of a final code that the user will compose step by step, answering to a well-defined sequence of questions as a function of the type of product and the belonging sector thereof, that is, the input data 110 inserted.

Below is an example of the composition of a final code of a conveyor.

Each belt conveyor is composed of several components:
commercial components (electric motors, bearings, supports, nuts and bolts etc.) with various dimensional and material types, which can be identified with a code starting with A followed by a progressive numbering for example with 4 positions: A0001-A0002-A0003, etc.
carpentry components (flanks, flanges, brackets etc.) with various dimensional and material types, which can be identified with a code starting with B followed by a progressive numbering for example with 4 positions: B0001-B0002-B0003, etc.
mechanical machining components (shafts, pins, spacers, etc.) with various dimensional and material types, which can be identified with a code starting with C followed by a progressive numbering for example with 4 positions: C0001-C0002-C0003, etc.
commercial components such as various types of belt/chain (belt/chain series X with food contact, series Y with food contact with high grip, etc.) with various dimensional and material types, which can be identified with a code starting with N followed by the initials of the belt X-Y, etc. and a numbering, for example, with 4 positions: NX0001-NX0002-NY0001-NY0002 etc.
commercial components such as various types of pinions for the belt/chain towing (pinion for belt/chain series X with food contact Z15 Diameter 90, pin for belt series Y with food contact with high grip Z12 diameter 110, etc.) with various dimensional and material types, which can be identified with a code starting with P followed by the initials of the belt X-Y etc. by the ratio Z15-Z12 etc. and by a numbering for example with 4 positions: PXZ150001-PXZ120002 etc.

And so on for any other group of components that will be coded: guides, sliding profiles, etc.

The user, by answering questions in sequence and that are very specific, will thus insert input data 101 which will create a code of well-defined components which consequently create his own belt conveyor.

Example of a sequence of identification codes of the type of belt conveyor created: A0001-A0105-A0099-B0001-B0020-B0501-NX0001-PXZ120001, etc.

Once the sequence of the identification codes of the type of belt conveyor and of each single component has been generated, it will be sent and processed by a PDM and/or software program, which will identify the respective technical bill of material 212 and the effective drawing codes, etc.

A preferred aspect provides that the questions, configured for the selection of corresponding input data 110, of each step, are displayed on at least one input interface 810 of a user graphic interface 800, as will be better described below.

Below is an example of a method relating to the insertion of input data 110, shown in FIGS. 2 to 29, to highlight the simplicity of the data 110 requested from the user, in the form of predefined input data 110.

In fact, they are basic input data 110 which do not require any technical skill related to the sector of design and manufacturing of belts conveyor.

Thanks to the figures it is also possible to well understand how said method guides the user step by step during the insertion of the information, without requiring specific skills from him.

By inserting a few basic input data 110, the method allows to provide for the display on the client device 100 of the output data 210 of the technical project 600 related to said one or more belts conveyor, preferably by using company software tools connected between them such as the proprietary server 200 and/or processing devices 201 that will be described below.

The examples of FIGS. 2 to 29 also show a possible user graphic interface 800 with a preferred input interface 810.

Said input data 110 can be already listed and proposed in the input interface 810 and the user has just to select them, or they can be inserted directly by the user.

As shown in FIGS. 2 to 29 the input interface 810 comprises request fields 801 which describes the type of input data 110 that is required and corresponding one or more insertion fields 802 in which the user must insert or select the value of said input data 110.

Said insertion field 802 can be configured to receive a value/string like in FIGS. 14, 17 or can be configured to provide one or more selectable input data 110 like in FIGS. 2, 3, 5, 4, 5, 6, 7, 8, etc.

The user graphic interface 800 may comprise a single input interface 810 in which all request fields 801 and corresponding insertion fields 802 to receive all the input data 110 through a single display are indicated.

Alternatively, a plurality of input interfaces 810 may be provided, for example sequential as illustrated in FIGS. from 2 to 29.

In particular, said method provides for example for the following input steps.

A first input step 1, provides for requesting to the user to select the sector data 111 displayed in an input interface 810; an example of said interface 810 is shown in FIG. 2 which displays a list of different productive sectors and requires the selection of the one which the belt conveyor has to operate in. In particular, the dairy sector is selected in the image. The inserted sector data 111 is then processed by the processing devices 201 restricting the previous database or opening a dependent database for the subsequent step. Furthermore, the selected sector data 111 is processed by the processing devices 201 to provide the correct output data 210.

A second input step 2, provides for requesting to the user to select the product data 112, displayed in an input interface 810; an example of said interface 810 is shown in FIG. 3 which displays and requires the selection of two possible options: whether the product, which is moved by the belt conveyor, is packaged with direct contact with the belt conveyor.

The selected product data 112 is then processed by the processing devices 201 restricting the previous database or opening a dependent database for the subsequent step.

Furthermore, the selected product data 112 is processed by the processing devices 201 to provide the correct output data 210.

In particular in this case, selecting the product data 112 related to the option product with direct contact with the belt conveyor, in the input database the choice of the belt chain is restricted among those suitable for treating food products with direct contact, or as regards the material for manufacturing the belt conveyor in the input database, the choice is restricted for example to stainless steel, and so on for other specifications linked to the product data 112 selected by the user.

A third input step 3, provides for requesting to the user to select the usage and maintenance data 111A displayed in an input interface 810; an example of said interface 810 is shown in FIG. 5 which displays and requires the selection of four possible options: whether the belt conveyor is washed with pressurised water and with aggressive detergents, or with pressurised water without aggressive detergents, or with depressurised water, or without using water.

The selected usage and maintenance data 111A is then processed by the processing devices 201 restricting the previous database or opening a dependent database for the subsequent step.

Furthermore, the selected usage and maintenance data 111A is processed by the processing devices 201 to provide the correct output data 210.

In this case, depending on the selected usage and maintenance data 111A, in the input database the choice is restricted, for example, to the materials of the belt suitable to avoid damage or wear due to the specific type of washing.

A fourth input step 4, provides for requesting to the user to select the environmental data 111B displayed in an input interface 810; an example of said interface 810 is shown in FIG. 7 which displays and requires the selection of four possible options in which it displays and requires the temperature range of the work environment in which the belt conveyor will be inserted: not less than 2° C. not more than 24°, not less than −15° C. not more than 2° C., not less than 20° C. not more than 50°, or other temperatures.

As for the previous steps, the selected environmental data 111B is then processed by the processing devices 201 restricting the previous database or opening a dependent database for the subsequent step.

Furthermore, the selected environmental data 111B is processed by the processing devices 201 to provide the correct output data 210.

A fifth input step 5 provides for requesting to the user to select the dimensional data 114 displayed in an input interface 810; an example of said interface 810 is shown in FIG. 11 which displays and requires the selection of three possible options in which it displays and requests whether the belt conveyor is straight, curvilinear, or elevator.

As for the previous steps, said selected dimensional data 114 is then processed by the processing devices 201 restricting the previous database or opening a dependent database for the subsequent step.

Furthermore, the selected dimensional data 114 is processed by the processing devices 201 to provide the correct output data 210.

A sixth input step 6 provides for requesting to the user to select further product data 112 displayed in an input interface 810; an example of said interface 810 is shown in FIG. 13 which displays and requires the selection of different possible options related to the type of product and/or package that will be moved by the belt conveyor.

This selected product data 112 is then processed by the processing devices 201 restricting the previous database or opening a dependent database for the subsequent step.

Furthermore, the selected product data 112 is processed by the processing devices 201 to provide the correct output data 210.

A seventh input step 7 provides for requesting to the user to select further product data 112, displayed in an input interface 810; an example of said interface 810 is shown in FIG. 14 which displays and requires the insertion of the length, width, height, weight of the package and motion direction of the product which will be moved by the belt conveyor.

As for the previous steps, said product data 112 are then processed by the processing devices 201 restricting the previous database or opening a dependent database for the subsequent step.

Furthermore, the selected product data 112 is processed by the processing devices 201 to provide the correct output data 210.

In fact, on the basis of said product data 112 inserted in step 7, the method preferably provides for an eighth input step 8, in which it provides for proposing to the user a further input data 110, in particular a dimensional data 114, dependent on the previous product data 112 and requesting the confirmation or replacement of said proposal; FIG. 15 shows for example an input interface 810 which displays an image of a portion of belt conveyor with a recommended width as a function of the product data 112 previously inserted and already processed. In fact, in order to be able to move a product with a certain size and a certain motion direction, the most suitable type of belt is automatically processed by the processing devices 201 and displayed. The user only needs to confirm whether he agrees with the processed proposal or alternatively insert a different value.

A ninth input step 9, provides for requesting to the user to select the dimensional data 114 displayed in an input interface 810; an example of said interface 810 is shown in FIG. 17 which displays the belt and requires the insertion of the length of the belt conveyor. Once the value has been inserted, an output interface 820 will appear with a summary image as shown in FIG. 19.

Similarly, FIG. 21 shows for example an input interface 810 which displays the belt and requests to the user to insert the height of the belt conveyor at the inlet and outlet directly on a dimension of the graphic representation. Once the value has been inserted, an output interface 820 will appear with a summary image as shown in FIGS. 22, 23, 24.

The inserted dimensional data 114 are then processed by the processing devices 201 restricting the previous database or opening a dependent database for the subsequent step.

Furthermore, the selected dimensional data 114 is processed by the processing devices 201 to provide the correct output data 210.

On the basis of said dimensional data 114 inserted in step 9, the method preferably provides for a tenth input step 10, in which it provides for proposing to the user a further input data 110 dependent on the previous dimensional data 114 inserted and requesting the confirmation or replacement of said proposal.

FIG. 26 shows for example an input interface 810 which displays an image of a portion of belt conveyor with the position of the supports on the ground or feet recommended for said belt conveyor.

As for the previous steps, all the input data 110 inserted are then processed by the processing devices 201 restricting the previous database or opening a dependent database for the subsequent step.

Furthermore, the selected input data 110 is processed by the processing devices 201 to provide the correct output data 210.

The method can also provide for other steps in addition to those described above and shown in FIGS. 2 to 29, such as, for example, steps for inserting other input 110, layout data 115, electrical data 116, etc.

The steps described above can also be presented with a different sequence.

Again, to ensure the use by users not expert in the field, the method, after performing one or more of the previous steps, provides for a summary step 20, related to displaying and/or requesting confirmation of all input data 110 inserted during said steps (1, 2, 3, 4, 5, 6, 7, 8, 9, 10).

Said summary step 20 provides for an input interface 810 like for example shown in FIG. 9, 16, 18, 20, 22, 23, 25, 27, 28, 29 by means of a table and/or graphic representation.

In particular FIG. 9 summarises for example steps 1, 2, 3, 4, or FIG. 16 summarises for example steps from 1 to 8, or FIGS. 18 and 20 summarises for example steps from 1 to 10 or FIG. 29 summarises all input data 110 both with table and with graphic representation and requires final confirmation by the user.

Furthermore, said method preferably provides for a confirmation step 30 for one or more of the previous steps 1, 2, 3, 4, 5, 6, 7, 8, 9, 10 or even for each one; said confirmation step 30 displays the input data 110 just inserted and requires the confirmation. FIG. 4, 6, 8, 10, 12, 20, 25, 27, 28 show for example an input interface 810 which displays an example of the confirmation step 30.

As shown in the figures, the confirmation step 30 can be associated with the summary step 20, by means of the same input interface 810. And so can an input step 1,2,3,4,5,6,7,8,9,10 be associated to the summary step 20.

Generally at the end of all aforesaid steps, the method provides for a step 40, in which the insertion of provision 117 and/or purchasing 118 and/or registration data 119 are requested from the user; FIG. 29 shows for example an input interface 810 which displays an example in which the input data 110 previously inserted are listed, then a summary and the user's personal data are requested for the registration and the type of purchase or quote request, etc.

It is understood however that what is described above has a value of non-limiting example, therefore, possible variants of detail that may be necessary for technical and/or functional reasons, are considered from now falling within the same protective scope defined by the claims indicated below.

By accepting the proposed data on the input interface 810, the method provides for the start of the output steps for the carrying out/entry into production of the technical project 600.

Said output steps differ according to the different types of provision that can be made for the client such as:
a first type of provision provides for the technical bill of materials 212 and/or related drawings of construction details 213 and/or assembly drawings 214 of said one or more belts conveyor;
a second type of provision provides for obtaining the constructive components encompassed in the technical bill of materials 212 and the provision to the client of said constructive components;
a third type of provision provides for the preparation of the mechanically mounted belt conveyor, or preassembled parts of the belt conveyor and the corresponding provision to the client.
a fourth type of provision may provide for the preparation of the electrically wired belt conveyor and the corresponding provision to the client.

To carry out aforesaid types of provision, the method provides for:
connecting the server of the owner 200 with one or more processing devices 201 implementing corresponding software adapted to receive the output data 210 of the technical project 600 and generating the activation of output steps related to the carrying out/entry into production of said technical project 600.

Therefore, processing devices 201 implementing corresponding software already present in the company are used to generate the codes defined by the output data 210.

For example, the method provides for connecting the server of the owner 200 with one or more processing devices 201 adapted to generate the technical bill of materials 212 and/or corresponding drawings of the construction details 213 and/or assembly drawings 214 of said one or more belts conveyor. Said processing devices 201 may be software already existing on the market such as CAD, PDM configurators, etc.

The codes defined by the output data 210 are processed by a CAD or PDM to generate a bill of materials 212 which comprises all the components necessary to manufacture the belt.

Said CAD or PDM software are also used to generate drawings of new construction details 213 and/or to identify already existing construction drawings 213, or the assembly drawing of the belt. Said method also provides for connecting the server of the owner 200 with one or more processing devices 201 adapted to generate the obtainment of the constructive components encompassed in the technical bill of materials 212 and the provision to the client of said constructive components.

Said processing devices 201 can be for example management software, CAD-CAM, etc.

This allows to obtain or physically manufacture the components of the belt conveyor whose codes are listed in the bill of materials 212. In particular, the management software generate purchase and production orders for aforesaid components.

The method may also provide for connecting the server of the owner 200 with one further or more processing devices 201 adapted to generate the preparation of the mechanically mounted belt conveyor, or preassembled parts of the belt conveyor and the corresponding provision to the client.

Said processing devices 201 can be management software, or warehouse management software, CAD software, etc.

Said processing devices 201 allow to carry out the assembly of the components obtained or manufactured in the previous step, by obtaining the components from the warehouse or from specific purchases and by providing assembly instructions by means of specific drawings.

Therefore, for example, once the technical bill of materials 212 of the identification codes of the type of belt conveyor and of each single component thereof has been generated, it is sent and processed by a PDM and/or management program.

For example: for each mechanical machining or carpentry detail, the PDM and/or management software identifies for example all the drawings with corresponding file to be sent to the tool machines for each type of machining and manufacturing; the management software sends the list of files to the corresponding work centres (for example for CNC tool machines with a file extension: .STEP .CAM .NC etc., for laser cutting machines .DXF or .DWG etc.).

For commercial components, a list is sent directly to suppliers or automatic warehouses for availability; as regards assembly, assembly drawings are sent to the appropriate company structures responsible for assembling the conveyor.

For data related to shipping and administration and order fulfilment, data are sent to the appropriate company structures.

Furthermore, the method may provide for connecting the server of the owner 200 with one or more processing devices 201 adapted to generate the preparation of the electrically wired belt conveyor and the corresponding provision to the client.

Said processing devices 201 can be, for example, electrical software, wiring configurators, etc.

In this way the method provides, by the software instructions, for interfacing the server of the owner 200 with all the processing devices 201 from time to time necessary for the carrying out of the type of project 600 required.

Said method also provides for storing the input data 110 and the output data 210 and respective input/output databases by means of storage means 700 preferably comprising an external server in particular a virtual server. Said virtual server can be, for example, a cloud server.

Furthermore, said storage means 700 allow to memorise all the input 110 and output 210 data of a determined project 600 of a specific client.

In this way, the client and/or the manufacturing company can retrieve data from previously inserted and possibly implemented projects, facilitating the retrieval of any technical provision specifications and keeping the historical memory of the projects connected to the corresponding clients.

The invention also relates to the system operating by software instructions for manufacturing a belt conveyor and/or a series of belts conveyor, according to the method described above characterized in that it comprises:
a client device 100 to provide/collect input data 110 in particular adapted to define technical specifications of the belt conveyor;
means for processing said input data 110 in particular adapted to define said technical specifications;
means for generating corresponding output data 210 which define a technical project 600 related to said one or more belts conveyor.

Said means for processing said input data 110 preferably comprise the proprietary server 200.

The means for generating corresponding output data 210 which define a technical project 600 related to said one or more belts conveyor preferably comprises the proprietary server 200 and/or processing devices 201.

An aspect of the invention provides that the system comprises means for processing said technical project 600 and defining a financial project 700 in particular the proprietary server 200 and/or processing devices 201.

Said system further comprises one or more of the following:
means for providing the acceptance of said technical project 600 and/or financial project 700, in particular the client device 100.
means for activating steps related to the carrying out/entry into production of the technical project 600, in particular processing devices 201.

One embodiment provides that the system comprises an input interface 810 of the client device 100 to provide/collect input data 110.

Preferably it also comprises an output interface 820 of the client device 100 to display output data 210 which define the technical project 600.

In particular said system can also comprise at least one of the following:
means for storing said software instructions implementing the method in particular the server of the owner 200;
means for connecting said server of the owner 200 and said client device 100 between them in particular by means of a connection network 300 in particular the internet network;
storage means 700 for storing the input data 110 and the output data 210 preferably comprising an external server in particular a virtual server;
means for providing the client with output data 210 comprising the technical bill of materials 212 and/or corresponding drawings of construction details 213 and/or assembly drawings 214, in particular processing devices 201;
means for obtaining the constructive components, in particular processing devices 201;
means for the preparation of the mechanically mounted belt conveyor, or preassembled parts of the belt conveyor, in particular processing devices 201;
means for the preparation of the electrically wired belt conveyor, in particular processing devices 201;
means for connecting the server of the owner 200 with one or more processing devices 201 implementing corresponding software adapted to receive the output data 210 of the technical project 600 and generating the activation of steps related to the carrying out/entry into production of said technical project 600.

The client device 100 comprising means for carrying out the method described above also forms the subject matter of the invention.

Said client device 100 preferably comprising an input interface 810 which comprises one or more of request fields 801 of the technical specifications of the belt conveyor and corresponding one or more insertion fields 802 to receive the input data 110 of the corresponding technical specifications of the belt conveyor.

A preferred embodiment provides that the insertion field 802 is configured to receive a value/string or is configured to provide one or more selectable options.

An embodiment provides that the client device 100 comprises the output interface 820 to display output data 210 which define the technical project 600 and/or to change the technical project 600.

The computer program comprising instructions that, when the program is run from a computer, makes the computer to implement the method described above also forms the subject matter of the invention.

The storage medium readable by a computer comprising instructions that, when run from a computer, makes the computer to implement the method described above also forms the subject matter of the invention.

A user graphic interface 800 comprising an input interface 810 and/or an output interface 820 configured according to the characteristics described above also forms the subject matter of the invention.

In summary, the method according to the invention provides for using a user graphic interface 800 comprising an input interface 810 of the client device 100 to provide/collect input data 110.

Said method provides for using the user graphic interface 800 comprising an output interface 820 of the client device 100 to display output data 210 which define the technical project 600.

Further, the method may provide for storing said software instructions implementing the method in a server of the owner 200.

According to another aspect, the method provides for connecting said server of the owner 200 and said client device 100 between them by means of a connection network 300 in particular the internet network.

Furthermore, the method can provide for transferring the input data 110 introduced through the client device 100 to the server of the owner 200 for their processing and generating corresponding output data 210 of the technical project 600 related to said one or more belts conveyor.

Said method can also transfer the output data 210 of the technical project 600 processed by the server of the owner 200 to the client device 100.

The method can provide for storing the input data 110 and the output data 210 by means of storage means 700 preferably comprising an external server, in particular a virtual server.

According to an aspect of the invention, the method is characterized in that the input interface 810 comprises one or more request fields 801 of the technical specifications of the belt conveyor and corresponding one or more insertion fields 802 to receive the input data 110 of the corresponding technical specifications of the belt conveyor and preferably said insertion field 802 is configured to receive a value/string, or it is configured to provide one or more selectable options.

Said method may provide for interacting with the output interface 820 to change the technical project 600.

Furthermore, the method can provide for operating directly on the graphic image 211 displaying the project 600.

The system operating by software instructions for manufacturing a belt conveyor and/or a series of belts conveyor forms the subject matter of the invention, configured to implement the method comprising at least:
a client device 100 to provide/collect input data 110 associated with technical specifications of the belt conveyor;
means for processing said input data 110 associated with the technical specifications;
means for generating corresponding output data 210 which define a technical project 600 related to said one or more belts conveyor.

Furthermore, the system can provide that the means for processing said input data 110 comprise the proprietary server 200.

Furthermore, the system wherein the means for generating corresponding output data 210 which define a technical design 600 related to said one or more belts conveyor comprises the proprietary server 200 and/or processing devices 201.

In accordance with aforesaid objects, the invention relates to a computer-readable storage medium comprising instructions that, when the program is run by a computer, makes the computer to implement the method according to any of the characteristics described above.

In accordance with aforesaid purposes, the invention relates to a user graphic interface 810 comprising an input interface 810 and/or an output interface 820 configured to implement the method according to any of the characteristics described above.

It is understood however that what is described above has a value of non-limiting example, therefore, possible variants of detail that may be necessary for technical and/or functional reasons, are considered from now falling within the same protective scope defined by the claims indicated below.

1. A method for manufacturing a belt conveyor and/or a series of belts conveyor, said method, implemented by software instructions, comprising:
providing input data (110) adapted to define technical specifications of the belt conveyor;
processing said input data (110);
generating corresponding output data (210) of a technical project related to said one or more belts conveyor;
connecting a client device (100) by means of a connection network (300) with a server of the owner (200), a server of the company manufacturing the belts conveyor, wherein input data (110) are inputted by a non-specialized technician client through a client device (100) and transferred to the server of the owner (200) for processing and generating corresponding output data (210);
transferring the output data (210) of the technical project (600) processed by the server of the owner (200) to the client device (100), providing an acceptance of said technical project (600) through the client device (100) and generating an activation of steps related to the carrying out/entry into production of the technical project (600);
defining an input database for the input data (110), and an output database comprising all possible output data (210) which can be used for manufacturing the belt conveyor and all possible codes that are used to compile a technical bill of materials (212) or a technical project (600), wherein said input database comprising a plurality of input databases each comprising input data (110),
wherein each input database is correlated in cascade with additional databases dependent on the selected input data (110) of the previous database, or an input database comprising input data (110) in which the selection of said input data (110) restricts said database to an increasingly reduced set of subsequent input data (110), to be selected which has the properties of the input data (110) already inserted, and the output database comprising a plurality of specific output databases for the respective components, for example database for the flanks, the guides, the support elements, the motors, etc., and each input data (110) inserted will restrict the choice within said specific output database of the respective component for the definition of the final component code, and said processing of said input data (110) generates an output data (210) through a plurality of stages or steps in cascade of entry of input data (110) by the user in the form of predefined input data (110), wherein each subsequent entry step is chosen as a function of the previous entry step and each step provides for a series of questions configured for the selection of corresponding input data (110) in which each choice of a given input data (110) defines a subsequent step which provides for further questions and a corresponding subsequent proposal of input data (110) which the user must select until is generated an output data (210) that is at least a portion of code which is completed with the subsequent steps until a complete code is generated which uniquely defines a component of a belt conveyor which is adapted to define the code of a technical bill of materials (212) and/or a drawing of a technical project (600) related to said one or more belts conveyor.

2. The method according to claim 1, wherein the input data (110) comprise at least one of:
sector data (111) to request and receive technical specifications related to the productive sector which the belt conveyor and/or the series of belts conveyor has to operate in;
product data (112) to request and receive technical specifications related to a product and/or products to be moved by the belt conveyor and/or the series of belts conveyor; or
production data (113) to request and receive technical specifications related to the production rate that the belt conveyor and/or the series of belts conveyor have to ensure.

3. The method according to claim 1, wherein the input data (110) comprise at least one of:
usage and maintenance data (111A) to request and receive technical specifications related to the type of cleaning, washing or sanitizing that is provided for the belt conveyor and/or the series of belts conveyor; or
environmental data (111B) to request and receive technical specifications related to environmental characteristics in which the installation of the belt conveyor and/or series of belts conveyor is provided for.

4. The method according to claim 1, wherein the input data (110) comprise at least one of:
dimensional data (114) to request and receive technical specifications related to the dimensional characteristics of the belt conveyor and/or the series of belts conveyor;
layout data (115) to request and receive technical specifications related to the relative positioning and/or within the operative area of the belt conveyor;
electric data (116) to request and receive technical specifications related to the electrical specifications and/or the wiring specifications of the belt conveyor;
provision data (117) to request and receive technical specifications related to the provision required by the client/user;
purchasing data (118) for the confirmation of the technical project and corresponding financial project for the continuation of the purchase; or
registration data (119) to request and receive technical specifications related to the data of the client/user who has made the request.

5. The method according to claim 1, wherein the output data (210) comprise at least one of:
a partial and/or total graphic image (211) adapted to display a partial and/or total configuration of the belt conveyor and/or the series of belts conveyor,
corresponding drawings of the construction details (213),
assembly drawings (214), or
technical manuals (215) for the assembling and operation of said one or more belts conveyor.

6. The method according to claim 1, wherein the questions configured for the selection of corresponding input data (110) of each step are displayed on at least one input interface (810) of a user graphic interface (800).
